(19) United States
(12) Patent Application Publication
(10) Pub. No.: US 2005/0116301 A1
(43) Pub. Date: Jun. 2, 2005

(54) High performance voltage controlled poly resistor for mixed signal and RF applications

(76) Inventors: Jonathan Alan Shaw, Fort Collins, CO (US); Jay Tatsuo Fukumoto, Fort Collins, CO (US); Sean Christopher Erickson, Fort Collins, CO (US)

Correspondence Address: LSI Logic Corporation;Legal Department - IP, MS D-106, 1621 Barber Lane, Milpitas, CA, 95035, US

(21) Appl. No.: 10/725,640

(22) Filed: Dec. 1, 2003

(51) Int. Cl. H01L 29/76

(52) U.S. Cl. 257/380

(57) ABSTRACT

A voltage-controlled, variable polysilicon resistor is formed of polysilicon deposited in the first interlayer dielectric layer at the same time that polysilicon routing is created. The polysilicon resistor, which is formed of n− doped polysilicon, has three contact regions connected to the metal layers. A region at either end of the resistor is doped n+ and forms the positive and negative terminals of the resistor. A third contact region is located within the polysilicon region between the first and second contacts to form a Schottky diode such that application of a voltage to this contact forms a depletion region within the polysilicon region. The depletion region changes in size depending on the voltage applied to the third contact to change the resistance of the depletion resistor.

### BACKGROUND OF THE INVENTION

1. Technical Field

The present invention relates generally to an improved circuit system and in particular to a resistor. Still more particularly, the present invention relates to a high-precision voltage controlled polysilicon resistor.

2. Description of the Related Art

A resistor is an electrical device that may convert energy into heat. The letter R is used to denote the resistance value of a resistor. With this device, two possible reference choices are present for the current and voltage at the terminals of the resistor. One is current in the direction of the voltage drop across the resistor and another is the current in the direction of voltage rise across the resistor.

Some existing problems with respect to resistors include transmission line impedance mismatching (caused by line width variations through etching), the physical size required for polysilicon resistors, and process variation in polysilicon resistors. Currently, existing solutions for these problems include special Microwave Integrated Circuit (MIC) processes to make trimmed resistors. This type of process involves using a laser to trim the resistors. The resistance is measured and a laser is used to reduce the size of the resistor. This type of process requires much time and is expensive to perform on a per circuit basis. Alternatively, high-precision discrete components are attached by soldering or bonding to an integrated circuit (IC) or package. These currently used solutions are expensive with respect to the manufacturing of semiconductors. Further, these existing solutions are difficult to integrate into a silicon IC process because of the size of components and/or specialized manufacturing requirements needed to trim the devices. Further, discrete or trimmed components are not adjustable after the manufacture of a product.

Therefore, it would be advantageous to have an improved polysilicon resistor that overcomes the problems of the existing solutions.

### SUMMARY OF THE INVENTION

The present invention provides a voltage-controlled, variable polysilicon resistor that is formed of polysilicon deposited in the first interlayer dielectric layer at the same time as polysilicon routing is created. The polysilicon resistor, which is formed of n− doped polysilicon, has three contact regions connected to the metal layers. A region at either end of the resistor is doped n+ and forms the positive and negative terminals of the resistor. A third contact region is located within the polysilicon region between the first and second contacts to form a Schottky diode such that application of a voltage to this contact forms a depletion region within the polysilicon region. The depletion region changes in size depending on the voltage applied to the third contact to change the resistance of the depletion resistor.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 is a cross-section of a voltage controlled variable resistor in accordance with a preferred embodiment of the present invention;

FIG. 2 is a cross-section of a non-salicided version of a variable resistor in accordance with a preferred embodiment of the present invention;

FIGS. 3A-3H are diagrams illustrating cross-sections in processing steps for creating a voltage controlled variable resistor in accordance with the preferred embodiments of the present invention; and

FIG. 4 is a schematic diagram of a radio frequency (RF) driver or receiver circuit with RF feedback in accordance with a preferred embodiment of the present invention.

### DETAILED DESCRIPTION

The present invention provides for an improved polysilicon resistor that is voltage controlled. The illustrative embodiments of the present invention take advantage of the fact that a Schottky diode is created when a metal comes into contact with a lightly doped n-type semiconductor. The depletion layer that results in the metal to semiconductor contact may be used in conjunction with a voltage bias on a Schottky diode to reduce or increase the effective resistance of a polysilicon resistor.

The structure of a high-precision voltage controlled polysilicon resistor in the illustrative embodiments of the present invention includes a low mobility polysilicon region with a positive contact at one end and a negative contact at the opposite end. A center tap is present consisting of the Schottky diode, formed by a metal contact to a region of polysilicon with a low concentration of an n-type dopant. The negative and positive contact regions are typical ohmic contacts.

Depending on the particular embodiment, a salicided region may be used at the contact interface while in another illustrative embodiment; only a metal contact is present. The resistance is made variable in these depicted examples through providing an ability to tune the resistor through a voltage-controlled contact (VCC). This contact is located at about center of the resistor structure in these examples. Since the contact acts as a Schottky diode, a depletion layer is created at the VCC interface, which partially depletes the thickness of the polysilicon resistor by a selected distance. Biasing the VCC contact changes the depletion thickness, which in turn alters the total conduction thickness. As a result, an increase or decrease in effective resistance in the structure is created depending on the particular voltage applied to the VCC contact. In this manner, an ability to vary the resistance of the polysilicon resistor through a voltage bias is accomplished.

The illustrative embodiments of the present invention provide for a reduction in physical resistor size. The reduction in the conduction thickness provides for creating a resistor of a higher value in the same space as a polysilicon resistor without the use of a Schottky contact. This advantage is accomplished in the depicted examples because the effective conduction thickness is reduced by “X_{d}”, the thickness of the depletion region. A basic polysilicon resistor has the same conduction thickness of “t”. In contrast, the polysilicon resistor of the present invention using a VCC has a conduction thickness of “t−X_{d}”. In these examples, the VCC may be tied to ground and an increase in the effective resistance still exists. By creating this resistor in the interlayer dielectric, there is less parasitics, less electrical noise, and less worry about injecting current into the substrate.

The processes, steps, and structures described below do not form a complete process flow for manufacturing integrated circuits. The present invention can be practiced in conjunction with integrated circuit fabrication techniques currently used in the art, and only so much of the commonly practiced process steps are included as necessary for an understanding of the present invention. The figures below represent cross sections of a portion of an integrated circuit during fabrication and are not drawn to scale, but to illustrate the important features of the invention.

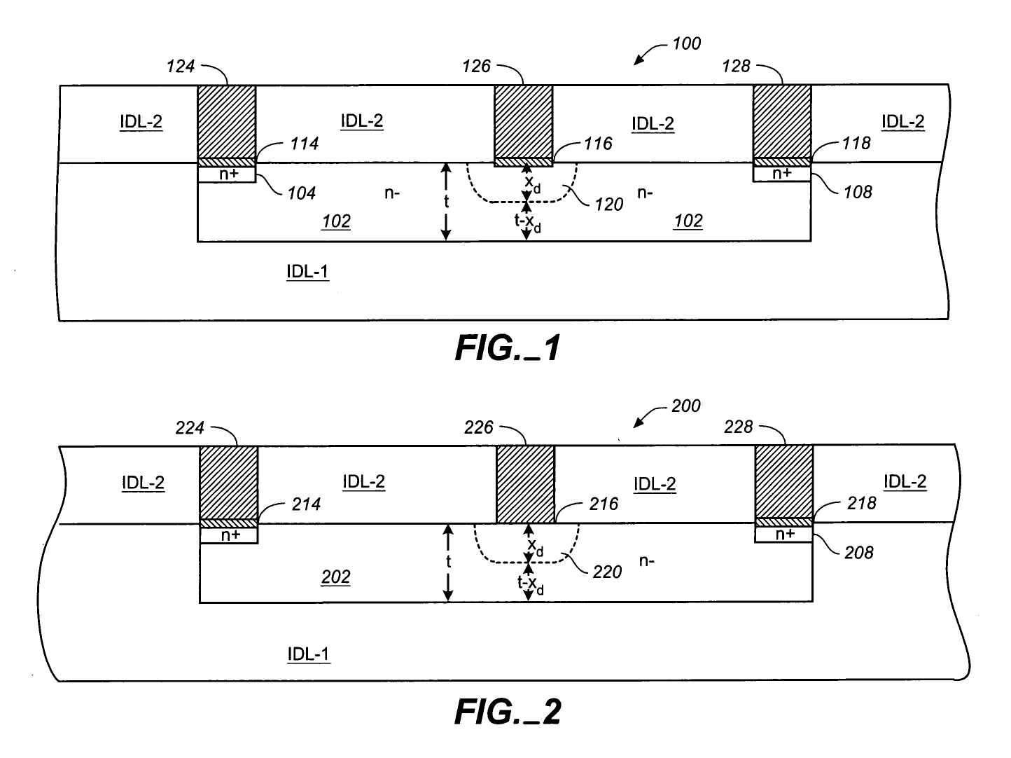

With reference now to the figures and in particular with reference to FIG. 1, a cross-section of a voltage controlled polysilicon resistor is depicted in accordance with a preferred embodiment of the present invention. In this example, polysilicon resistor 100 is formed within the first interlayer dielectric layer IDL-1. The dielectric layer IDL-1 is an insulator, and can comprise, for example, silicon dioxide (SiO₂). IDL-1 is deposited on the substrate of a circuit once all processing within the substrate is completed. The region where polysilicon resistor 100 is to be created is etched to create a recessed strip surrounded by the dielectric layer IDL-1. Polysilicon layer 102 is deposited, then doped with an n-type dopant to form an n− region. The n-type dopant can be arsenic or phosphorus, for example. As illustrated, n+ contact region 104 and n+ contact region 108 are formed within polysilicon region 102. Contacts 124, 126, and 128 are formed on salicided regions 114, 116, and 118. Salicided region 114 is formed on n+ contact region 104, and salicided region 118 is formed on n+ contact region 108. These contacts are standard ohmic contacts formed by metal layers. Contact 124 in this example is a positive terminal for polysilicon resistor 100, while contact 128 forms a minus terminal for polysilicon resistor 100. Contact 126 is a voltage control contact (VCC) for a Schottky diode. Depending on the voltage bias applied to contact 126, depletion region 120 is formed and may grow or shrink.

As voltage is applied to contact 126, depletion region 120 grows in size. In particular, x_{d} represents the depth of depletion region 120. This value increases as voltage is applied to contact 126. In this example, t represents the thickness of region 102 and also represents the conductivity. The overall conductivity is controlled as a function of t−x_{d} in which the conductivity decreases as x_{d} increases with the size of depletion region 120.

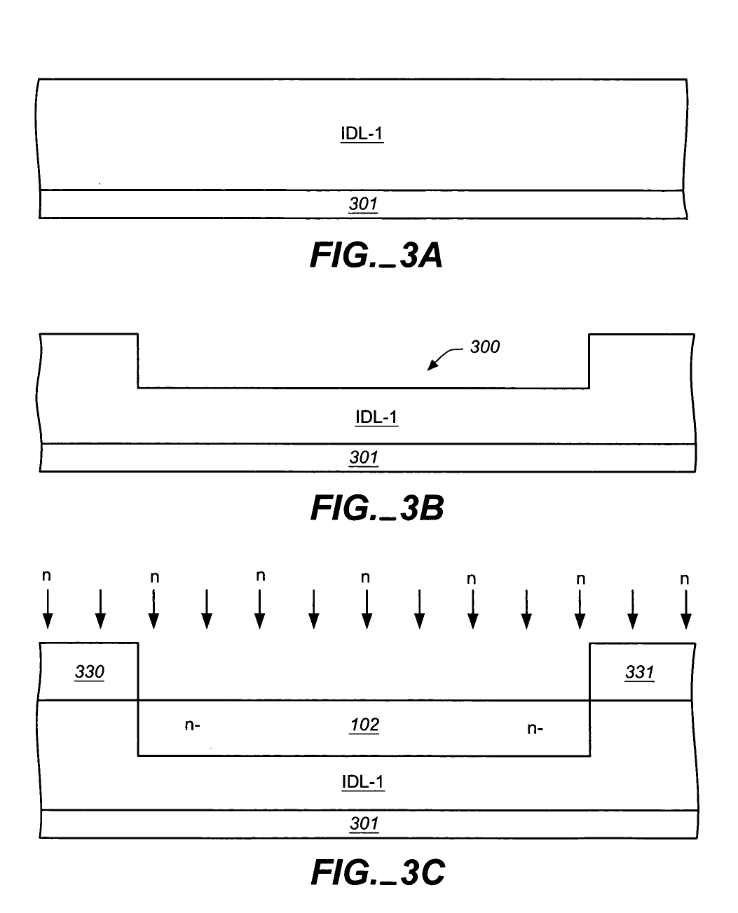

Turning next to FIG. 2, a non-salicided version of a polysilicon resistor is depicted in accordance with a preferred embodiment of the present invention. Polysilicon resistor 200 is essentially identical to polysilicon resistor 100 in FIG. 1. As can be seen, polysilicon region 202 is formed within and surrounded by interlayer dielectric layer IDL-1. Within polysilicon region 202 are n+ contact region 204 and n+ contact region 208. Contact 224 and contact 228 are formed over salicided regions 214 and 218, which are formed over n+ contact regions 204 and 208. Further, contact 226 is formed on region 220. In this example, however, a salicided region is absent. As with polysilicon resistor 100 in FIG. 1, depletion region 220 is formed and may increase or decrease in size depending on the voltage bias applied to contact 226.

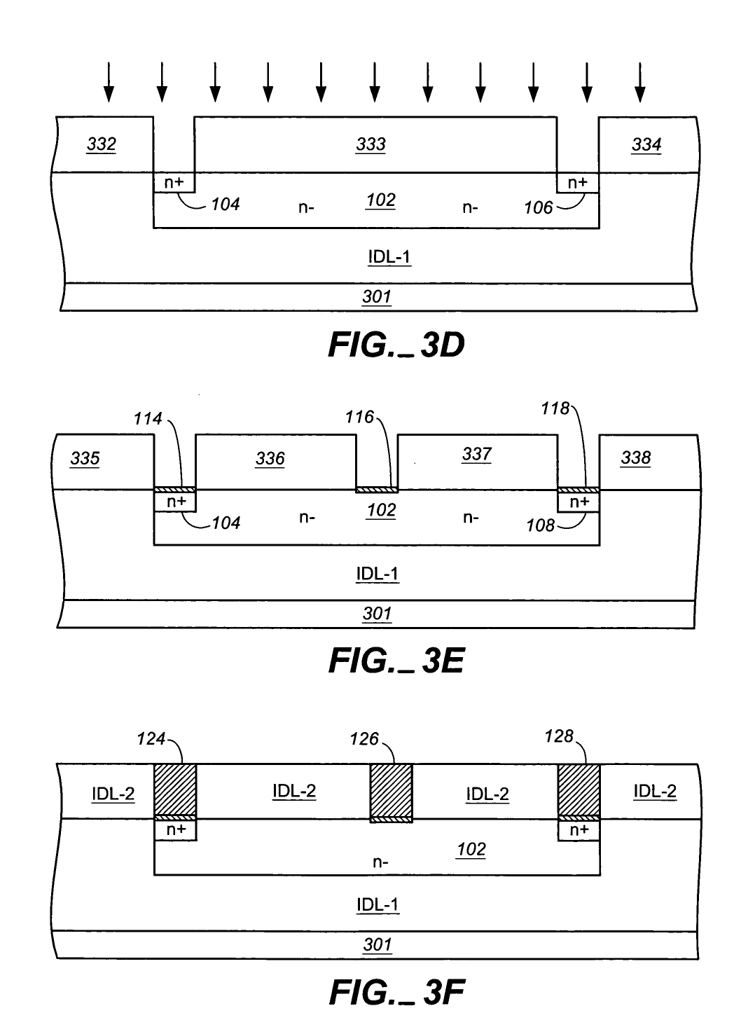

Turning now to FIGS. 3A-3H, diagrams illustrating cross-sections in processing steps for creating a voltage controlled polysilicon resistor are depicted in accordance with the preferred embodiments of the present invention. In FIG. 3A, processing on the substrate 301 has been completed; a first dielectric layer IDL-1 is then deposited. Preferably, chemical/mechanical polishing (CMP) is used to planarize IDL-1, then a layer of polysilicon 302 is deposited. In FIG. 3B, a resist layer RST has been deposited and patterned to expose the region that will be the resistor. The exposed portions of polysilicon are then implanted with an n-type dopant. In this example, the dopant may be, for example, phosphorous or arsenic. The implant is performed to result in a low concentration of n-type dopants throughout the exposed portion of layer 302. These dopants in these examples have a concentration of about 1×10 ¹⁵ per cm³.

In FIG. 3C, the old resist has been removed and a new photo resist layer RST has been deposited over the polysilicon layer 302 and patterned to expose the desired contact regions at the ends of the resistor. Shown is an n-type dopant being implanted into the device to form n+ contact region 304 and n+ contact region 306. This implant step increases the concentration of n-type dopants in the contact regions, typically creating a concentration range of from 1×10¹⁸ per cm³ to 1×10²⁰ per cm³.

In FIG. 3D, a further new resist pattern has been formed on the device, covering the regions that will become the resistor and exposing the surrounding area. The device is then etched to remove the unneeded polysilicon. The portion of polysilicon layer 302 that remains corresponds to the body 102 of the resistor of FIG. 1. A second layer of interlayer dielectric IDL-2 is deposited and planarized, giving the section shown in FIG. 3E. Thereafter, formation of the metal contacts can begin.

In FIG. 3F, a new resist layer is deposited and patterned to expose the regions of the resistor which must be contacted by electrical leads. The exposed portions of IDL-2 are then etched to remove the dielectric. Moving next to FIG. 3G, salicided regions 308, 310, and 312 are formed. These regions are formed by deposition of a refractory metal followed by a rapid thermal anneal process. In those regions where the refractory metal contacts silicon, the annealing process causes the metal and silicon to react to form a salicide. As shown in FIG. 2, formation of salicided region 216 (corresponding to 310 in FIG. 3G) may be blocked depending on the particular implementation or processing used. By avoiding the creation of this salicided region, the effect of the schottky diode is enhanced. However, blocking formation of this region complicates the typical processing of the device. Therefore, depending on the particular implementation, the salicided regions may remain. A salicided contact region is more common in CMOS devices. These schottky diode regions are used to increase the effective resistance of the device. The refractory metal used for salicided regions 308, 310, and 312 is typically titanium or cobalt. Finally, in FIG. 3H, a refractory metal is deposited into the contact regions to form contacts 314, 316, and 318, with the refractory metal typically being tungsten.

In these examples, the length “l” and the thickness “t” of the lightly doped area 102 are preferably minimized to maximize the effect of the voltage effect on the resistor.

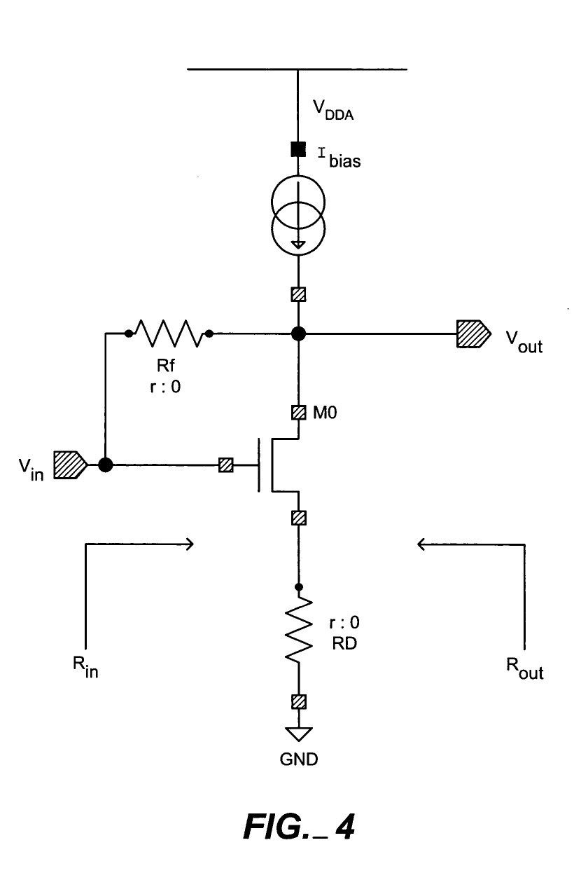

Turning now to FIG. 4, a schematic diagram of an RF driver or receiver circuit with Rf feedback is depicted in accordance with a preferred embodiment of the present invention. In these examples, the Rf feedback employs a variable resistor, such as the variable resistor in the illustrated examples. In this example, circuit 400 includes current source 402, transistor 404, resistor 406, and resistor 408. In these examples, resistor 406 is an Rd resistor connecting transistor 404 to ground. Current source 402 has one end connected to transistor 404 and another end connected to voltage source VDD. Further, transistor 404 and current source 402 are connected to Vout. Vin is connected to the gate of transistor 404 and resistor 408. In these examples, resistor 408 is a variable polysilicon resistor as illustrated in the depicted examples.

Thus, the present invention in the illustrated examples provides for an adjustable or tunable resistance value in a polysilicon resistor. The absolute value of the resistor in these examples may be modified with a voltage bias on the metal contact of the Schottky diode. By changing the voltage bias, the thickness of the resistor may be increased or decreased. With this feature, impedance matching adjustment for radio frequency (RF) driver/receiver circuits may be made. The voltage controlled polysilicon resistor in the illustrated examples allows for adjustment of the resistor value Rᵢₙ for a receiver application or Rₒᵤₜ for a driver application to match the transmission line impedance. In this manner, unwanted voltage reflections and signal loss are reduced or eliminated. With proper circuit design techniques, resistance values can be self-adjusting, such as implementation in a feedback technique. The resistance value can be adjusted to compensate for process variation.

Further, adjustments to resistance allow for a bias current adjustment for mixed signal circuits. Also, the reduction in the size of the resistor is accomplished by reducing the resistor thickness. Additionally, resistance values may be self-adjusting through various circuit design techniques, such as implementing a feedback circuit with the resistor of the present invention. Further, the variable resistance value may be adjusted to compensate for process variations to provide for uniform resistance. Also, the variable resistance may be adjusted to a very high resistance to put an analog circuit in a low current or low power sleep mode. Finally, the process to make the resistors can be easily integrated into the process, as it can be designed to require no additional steps.

The description of the preferred embodiment of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention the practical application to enable others of ordinary skill in the art to understand the invention for various embodiments with various modifications as are suited to the particular use contemplated.

1. A polysilicon resistor comprising:
a first interlayer dielectric layer overlying a substrate;
a polysilicon region formed in said interlayer dielectric;
a first contact region extending down from a surface of said first interlayer dielectric;
a second contact region extending down from said surface of said first interlayer dielectric;
a first contact connected to said first contact region;
a second contact connected to said second contact region; and
a third contact connected to a surface of said polysilicon region, wherein said third contact is located between said first contact and said second contact, wherein said third contact forms a Schottky diode such that application of a voltage to said third contact forms a depletion region that changes in size depending on a voltage applied to said third contact, thereby changing a resistance in said depletion resistor.

2. The polysilicon resistor of claim 1, wherein said third contact is connected to said surface by a salicided region.

3. The polysilicon resistor of claim 1, wherein said polysilicon region is doped with an n-type doping.

4. The polysilicon resistor of claim 3, wherein said first contact region and said second contact region are n+ contact regions.

5. The polysilicon resistor of claim 1, wherein said first contact, said second contact, and said third contact are formed using metal layers.

6. The polysilicon resistor of claim 5, wherein the metals layers are tungsten metal layers.

7. The polysilicon resistor of claim 1, wherein said polysilicon region contains n-type dopants having a concentration of about 1×10¹⁵/cm³.

8. The polysilicon resistor of claim 1, wherein said first contact region and said second contact region contain n-type dopants having a concentration of about 1×10¹⁸/cm³ to about 1×10²⁰/cm³.

9. A chip comprising:
a substrate on which a plurality of elements of an integrated circuit are formed;
a first interlayer dielectric layer overlying said substrate;
a polysilicon region formed in said interlayer dielectric;
a first contact region extending down from a surface of said first interlayer dielectric;
a second contact region extending down from said surface of said first interlayer dielectric;
a first contact connected to said first contact region;
a second contact connected to said second contact region; and
a third contact connected to a surface of said polysilicon region, wherein said third contact is located between said first contact and said second contact, wherein said third contact forms a Schottky diode such that application of a voltage to said third contact forms a depletion region that changes in size depending on a voltage applied to said third contact, thereby changing a resistance in said depletion resistor;
wherein said polysilicon region forms a resistor for said integrated circuit.

10. The chip of claim 9, wherein said third contact is connected to said surface by a salicided region.

11. The chip of claim 9, wherein said polysilicon regions is doped with an n-type doping.

12. The chip of claim 11, wherein said first contact region and said second contact region are n+ contact regions.

13. The chip of claim 9, wherein said first contact, said second contact, and said third contact are formed using metal layers.

14. The chip of claim 13, wherein the metals layers are tungsten metal layers.

15. The chip of claim 9, wherein said polysilicon region contains n-type dopants having a concentration of about 1×10¹⁵/cm³.

16. The chip of claim 9, wherein said first contact region and said second contact region contain n-type dopants having a concentration of about 1×10¹⁸/cm³ to about 1×10²⁰/cm³.

17. A method for forming a polysilicon resistor, the method comprising:
forming a doped polysilicon region in a interlayer dielectric layer;
forming a first contact region and a second contact region in said doped polysilicon region, wherein said first contact region and said second contact region extend downward from a surface of said polysilicon;
forming a first contact on said first contact region and a second contact on said second contact region; and
forming a third contact on a surface of said doped polysilicon region, wherein said third contact is located between said first contact and said second contact, wherein said third contact forms a Schottky diode such that application of a voltage to said third contact forms a depletion region that changes in size depending on a voltage applied to said third contact, thereby changing a resistance in said depletion resistor.

18. The method of claim 17, wherein said step of forming said doped polysilicon region comprises:
removing a given region of an interlayer dielectric layer;
filling said given region with polysilicon;
implanting n-type dopants into said polysilicon.

19. The method of claim 18, wherein said n-type dopants implanted into said polysilicon region have a concentration of about 1×10¹⁵/cm³.

20. The method of claim 18, wherein a doping profile of the n-type dopants is selected to reduce parasitic capacitance.

21. The method of claim 18, wherein the step of forming said first contact region and said second contact region comprises:
implanting n-type dopants into portions of said polysilicon region in a concentration of about 1×10¹⁸/cm³ to about 1×10²⁰/cm³.

22. The method of claim 18, wherein the step of forming said first contact and said second contact comprises:
depositing a metal layer onto said first contact region and said second contact region.

23. The method of claim 22, wherein said metal layer is a tungsten metal layer.

24. The method of claim 18, wherein said doped polysilicon region receives an n-type doping.
